(19) United States
(12) Patent Application Publication
(10) Pub. No.: US 2013/0300411 A1
(43) Pub. Date: Nov. 14, 2013

(54) TRIANGLE COIL ARRANGEMENT

(71) Applicant: New York University, New York, NY (US)

(72) Inventor: Graham Charles Wiggins, New York, NY (US)

(73) Assignee: New York University

(21) Appl. No.: 13/866,213

(22) Filed: Apr. 19, 2013

Related U.S. Application Data
(60) Provisional application No. 61/635,815, filed on Apr. 19, 2012.

(51) Int. Cl. G01R 33/20; H01Q 1/52; H01Q 21/06

(52) U.S. Cl. CPC G01R 33/20; H01Q 21/06; H01Q 1/523
USPC 324/307; 343/893; 343/841

(57) ABSTRACT

An array arrangement can be provided, that, for example, can include a plurality of triangular antenna arrangements, which can be configured to transmit or receive a magnetic resonance signal(s). A processing arrangement can be configured to generate information associated with a magnetic resonance image based on the magnetic resonance signal(s). A shield arrangement can be configured to shield the triangular antenna arrangements.

### CROSS-REFERENCE TO RELATED APPLICATIONS

This application relates to and claims priority from U.S. Patent Application No. 61/635,815, filed on Apr. 19, 2012, the entire disclosure of which is incorporated herein by reference.

### FIELD OF THE DISCLOSURE

The present disclosure generally relates to a medical imaging apparatus, and more specifically, relates to exemplary embodiments of a triangle coil array arrangement, which can include a decoupled multi-channel transmit-receive loop array that can be used at 7T with diverse B1 profiles.

### BACKGROUND INFORMATION

Transmit array coils can be used for a parallel transmission at high field. In a typical encircling array, neighboring elements can be decoupled by various means, however, it can be more difficult to mitigate the often substantial coupling between next nearest neighbor coils, for example, coils next to adjacent coils. Existing designs can reduce this coupling through the use of shielded elements such as striplines or shielded loops, or can reduce the size of the individual elements, although these traditional strategies can have the negative side effect of decreasing the transmit efficiency of the elements, for example, as compared to a conventional surface coil loop.

Thus, it may be beneficial to provide an exemplary coil arrangement that can be decoupled, and can address and/or overcome at least some of the above-described deficiencies.

### SUMMARY OF EXEMPLARY EMBODIMENTS

To address at least some of these drawbacks and/or deficiencies, an exemplary multi-channel (e.g., 8 channel) coil array arrangement (e.g., a Transmit-Receive (“TxRx”) array) can be provided according to certain exemplary embodiments of the present disclosure which can include triangular elements which can facilitate capacitive decoupling of neighbors, and inductive decoupling of next nearest neighbors, which can result in a highly decoupled array that can retain the transmit efficiency of a large surface coil loop element.

In certain exemplary embodiments of the present disclosure, arrangements, methods of making/using arrangements, and/or computer readable mediums can be provided which can include and/or utilize an array arrangement that can include a plurality of triangular antenna elements configured to transmit and/or receive at least one magnetic resonance signal. According to further exemplary embodiments of the present disclosure, a processing arrangement can be provided that can be configured to determine a magnetic resonance image based on the magnetic resonance signal(s). In certain exemplary embodiments, the triangular antenna elements can have alternating orientations. For example, neighboring elements can be decoupled through the use of capacitors in their shared leg. In certain exemplary embodiments of the present disclosure, neighboring elements can be decoupled through the use of overlap. Next nearest neighbors can be decoupled through the use of an inductive circuit. According to certain exemplary embodiments of the present disclosure, the next nearest neighbors can be decoupled through the use of a capacitive circuit.

These and other objects of the present disclosure can be achieved by provision of an array arrangement that can include a plurality of triangular antenna arrangements configured to transmit or receive a magnetic resonance signal(s). A processing arrangement can be configured to generate information associated with a magnetic resonance image based on the magnetic resonance signal(s). In certain exemplary embodiments of the present disclosure, at least two ones of the triangular antenna arrangements can have alternating orientations. At least two neighboring ones of the triangular antenna arrangements can be decoupled using a capacitor(s) in a leg(s) shared by the two neighboring ones of the triangular antenna arrangements. In some exemplary embodiments of the present disclosure, at least two neighboring ones of the triangular antenna arrangements can be decoupled by overlapping the at least two neighboring one of the triangular antenna arrangements. Next nearest neighboring ones of the triangular antenna arrangements can be decoupled using an inductive circuit or a capacitive circuit.

In certain exemplary embodiments of the present disclosure, the triangular antenna arrangements can include at least 8 triangular antenna arrangements. The triangular antenna arrangements can be structured as large loops. In some exemplary embodiments of the present disclosure, the triangular antenna arrangements are unshielded. In certain exemplary embodiments of the present disclosure, gaps between each of the triangular antenna arrangements can be provided that are sized close to or equal to zero. In certain exemplary embodiments of the present disclosure, the triangular antenna arrangements can have different sensitivity profiles.

In some exemplary embodiments of the present disclosure, the triangular antenna arrangements can have a substantially low coupling when the triangular antenna arrangements can be configured to transmit the magnetic resonance signal(s), the coupling can be less that −15 dB. The triangular antenna arrangements can also be configured to be used in parallel transmission when the triangular antenna arrangements transmit the magnetic resonance signal(s). A preamp decoupling arrangement can be configured to preamp decouple the triangular antenna arrangements when the triangular antenna arrangements receive the magnetic resonance signal(s). The triangular antenna arrangements can also be configured to be used in parallel imaging when the triangular antenna arrangements receive the magnetic resonance signal(s).

In some exemplary embodiments of the present disclosure, a shield arrangement can be configured to shield the triangular antenna arrangements. The shield arrangement can be segmented to reduce gradient coil induced eddy currents on the shield. A pattern of the segments can be configured to track a current path of the shielded triangular antennas arrangements. In certain exemplary embodiments of the present disclosure, a capacitor(s) can be coupled to one segment(s), and can be configured to provide radio frequency continuity in a path, which can track a current path of the shielded triangular antennas arrangements. An end cap can be provided at an end of each of the triangular antenna arrangements, or an endcap can be provided at at least one triangular antenna arrangement.

These and other objects, features and advantages of the present disclosure will become apparent upon reading the following detailed description of exemplary embodiments of the present disclosure, when taken in conjunction with the accompanying exemplary drawings and appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIGS. 1A and 1B are exemplary circuit diagrams of previously known coil arrangements providing comparative coil designs;

FIG. 1C is an exemplary circuit diagram of an exemplary triangular array arrangement according to an exemplary embodiment of the present disclosure;

FIG. 2 is an exemplary illustration of an exemplary triangular array arrangement according to an exemplary embodiment of the present disclosure;

FIG. 3A is an exemplary image of an exemplary coupling matrix for the previously known capacitively decoupled array;

FIG. 3B is an exemplary image of an exemplary coupling matrix for an exemplary triangular array arrangement according to an exemplary embodiment of the present disclosure;

FIG. 4 is a set of exemplary illustrations of exemplary signal-to-noise ratio plots based on a root sum of squares reconstruction procedure for the exemplary birdcage, the exemplary capacitively decoupled array and the exemplary triangular array arrangement;

FIG. 5 is a set of exemplary illustrations of exemplary plots of g-factor values for the exemplary capacitively decoupled array and the exemplary triangular array arrangement;

FIG. 6A is an exemplary illustration of exemplary B1+ maps for the exemplary capacitively decoupled coil arrangement as a function of Z position;

FIG. 6B is an exemplary illustration of exemplary B1+ maps for an exemplary triangular array arrangement as a function of Z position according to an exemplary embodiment of the present disclosure;

FIG. 7 is an exemplary system, including an exemplary computer-accessible medium, according to an exemplary embodiments of the present disclosure;

FIG. 8 is an exemplary illustration of exemplary dimensions of a cross-section for an exemplary triangular array arrangement according to an exemplary embodiment of the present disclosure;

FIG. 9 is an exemplary illustration of an exemplary circuit board design for an exemplary triangular array arrangement according to an exemplary embodiment of the present disclosure;

FIG. 10 is an exemplary illustration of a further exemplary triangular array arrangement according to an exemplary embodiment of the present disclosure;

FIG. 11 is a set of exemplary illustrations of exemplary head images acquired with the exemplary triangular array arrangement shown in FIG. 10 according to an exemplary embodiment of the present disclosure;

FIG. 12 is a set of exemplary illustrations of exemplary signal-to-noise ratio maps according to an exemplary embodiment of the present disclosure;

FIG. 13 is an exemplary illustration of an exemplary circuit board design for an exemplary shielded triangular array arrangement according to an exemplary embodiment of the present disclosure;

FIG. 14 is an exemplary schematic diagram illustrating exemplary components of an exemplary shielded triangular array arrangement according to an exemplary embodiment of the present disclosure;

FIG. 15 is an exemplary image illustrating how the shield of the exemplary shielded triangular array arrangement can be partitioned to prevent gradient coil induced eddy currents according to an exemplary embodiment of the present disclosure;

FIG. 16 is an exemplary circuit diagram for a matching circuit for the exemplary shielded triangular array arrangement according to an exemplary embodiment of the present disclosure;

FIG. 17 is a set of exemplary images illustrating endcap optimization according to an exemplary embodiment of the present disclosure;

FIG. 18 is an exemplary image illustrating a coupling matrix for the exemplary shielded triangular array arrangement according to an exemplary embodiment of the present disclosure;

FIG. 19 is a set of exemplary images illustrating a comparison of the exemplary shielded triangular array arrangement compared to a previously known Nova 24ch system;

FIG. 20 is a set of exemplary images illustrating a signal-to-noise ratio comparison between the exemplary shielded triangular array arrangement and the exemplary non-shielded triangular array arrangement according to an exemplary embodiment of the present disclosure;

FIG. 21 is a further set of exemplary images illustrating a signal-to-noise ratio comparison between the exemplary shielded triangular array arrangement and the exemplary non-shielded triangular array arrangement according to an exemplary embodiment of the present disclosure;

FIG. 22 is a set exemplary images illustrating B₁⁺ comparison between the exemplary shielded triangular array arrangement and a previously known Nova 24ch array; and

FIG. 23 is a set of exemplary images illustrating individual B₁⁺ maps for the exemplary shielded triangular array arrangement according to an exemplary embodiment of the present disclosure.

Throughout the drawings, the same reference numerals and characters, unless otherwise stated, are used to denote like features, elements, components, or portions of the illustrated embodiments. Moreover, while the present disclosure will now be described in detail with reference to the figures, it is done so in connection with the illustrative embodiments and is not limited by the particular embodiments illustrated in the figures or accompanying claims.

### DETAILED DESCRIPTION OF EXEMPLARY EMBODIMENTS

To test the exemplary triangular coil arrangements, three exemplary embodiments of coils (e.g., two previously known coil arrays and the exemplary triangular coil array) can be built on identical or substantially similar cylindrical formers, for example, being about 15.24 cm in diameter. The conductive structures can be machined from FR4 circuit board, and all conductors can be of 1 cm width. The length of the each coil can be 12.5 cm. A phantom (e.g., an artificial test subject) can be constructed with an inner diameter of 6 cm and length of 24 cm consisting of corn syrup, distilled water and salt with εr=57.5 and σ=0.8 to mimic average tissue properties at 297 MHz.

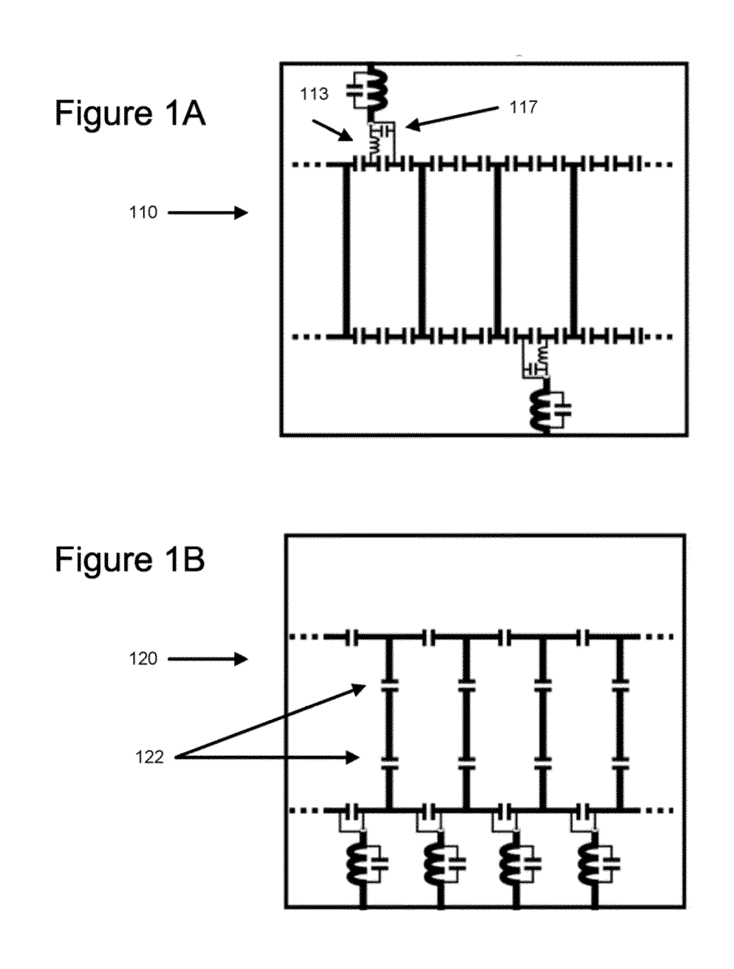

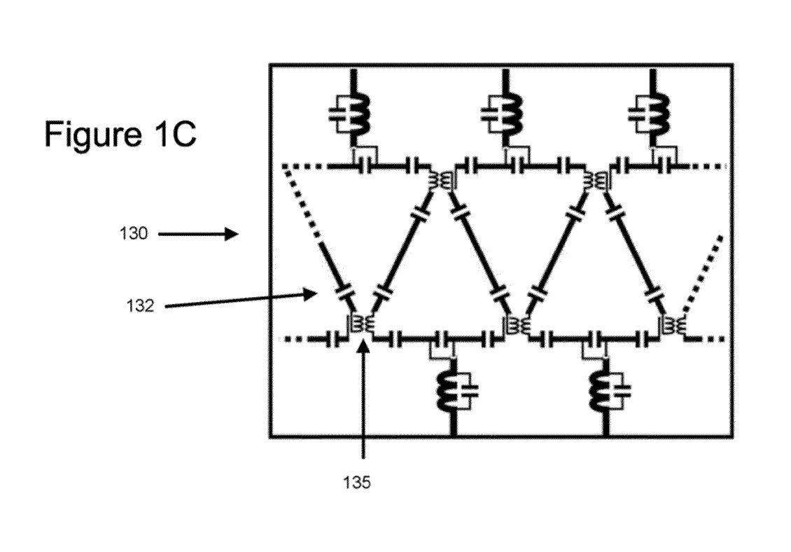

One exemplary previously known coil can be a high pass birdcage 110 (“Birdcage”) with a four port drive, for example, as shown in the diagram of FIG. 1A. A second previously known exemplary coil can be an array of 8 rectangular surface coils 120 (“CDA”) which can be capacitively decoupled from their neighbors via their shared edges and capacitors 122, for example, as shown in a diagram of FIG. 1B. The exemplary triangular coil, according to an exemplary embodiment of the present disclosure, can consist of 8 triangular elements 130 which can be capacitively decoupled from their neighbors (e.g., with capacitors 132) and also inductively decoupled from their next nearest neighbors (e.g., with inductors 135), for example, as shown in a diagram of FIG. 1C.

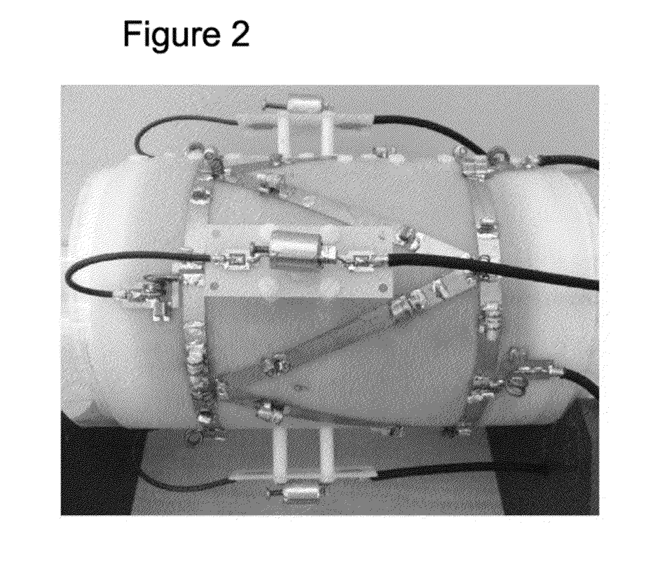

The surface coil arrays (e.g., 120 and 130) can be matched to 50Ω coax by attaching the ground and signal lines of the coax to either side of a capacitor in the surface coil loop. The birdcage 110 can include a series inductor 113 and parallel capacitor 117 to match to the coax. A coaxial trap can be placed next to each match circuit to minimize common mode currents on the cables. For the coils with match circuits at both ends, the coax can be routed back across the coil through an additional trap, such as shown in FIG. 2.

The exemplary birdcage 110 can be driven with an in-house built 4 channel power splitter, transmit/receive (“T/R”) switch and preamp interface, with appropriate phases applied to the ports through the control of cable length. Signals from the four ports can be recorded, reconstructed and combined in Root Sum of Squares (“RSS”) combination. For the 8 channel arrays, power can be divided with an 8 way splitter (e.g., from Werlatone of Patterson N.Y.) and the coil can be connected to the scanner with an in-house built 8 channel T/R switch and preamp interface. Signals from all 8 ports can be recorded and combined as above. All data can be acquired on a Siemens 7T scanner (e.g., from Siemens Healthcare of Erlangen, Germany).

To determine the radio frequency (“RF”) voltage to achieve a 90 degree flip angle in the center of the phantom, a turbo-FLASH sequence with various preparation pulses can be used [see 1]. The B1+ distribution can be mapped with a similar method using a manufacturer works-in-progress sequence (e.g., from Siemens Healthcare of Erlangen, Germany) [see 2]. Signal-to-noise ratio (“SNR”) can be measured using gradient echo acquisitions both with and without the RF excitation and calculated according to the “Kellman” method/procedure [see 3]. Exemplary G-factor maps can be derived from the same gradient echo sequence but with field of view set tight on the phantom to maximize aliasing.

These particular exemplary embodiments describe certain exemplary configurations, exemplary settings, and exemplary implementations related to certain exemplary results discussed for illustrative purposes. However, other configurations, settings, and implementations may also be possible to produce the same, similar or different results, for example, as defined and/or described in other exemplary embodiments of the present disclosure.

Exemplary Results

The exemplary phantom, which can substantially fill the volume of the coil, can present a heavy load. This can make it difficult to match and decouple the ports of the birdcage since the coil can become overdamped. Using 4 ports (e.g., 2 on each end ring a symmetrical excitation can be forced, although coupling between the ports can be high (e.g., −11 dB). QUL/QL can be 10 for the capacitively decoupled array 120 (“CDA”) and 5.7 for the exemplary triangle array 130. For the CDA 120, coupling between next nearest neighbors can be −11.6 dB, for example, when there can be the only two coils active. It can be difficult to decouple neighboring coils through adjustment of the capacitors in their shared legs, but 2 coils in isolation can achieve isolation of −15 dB.

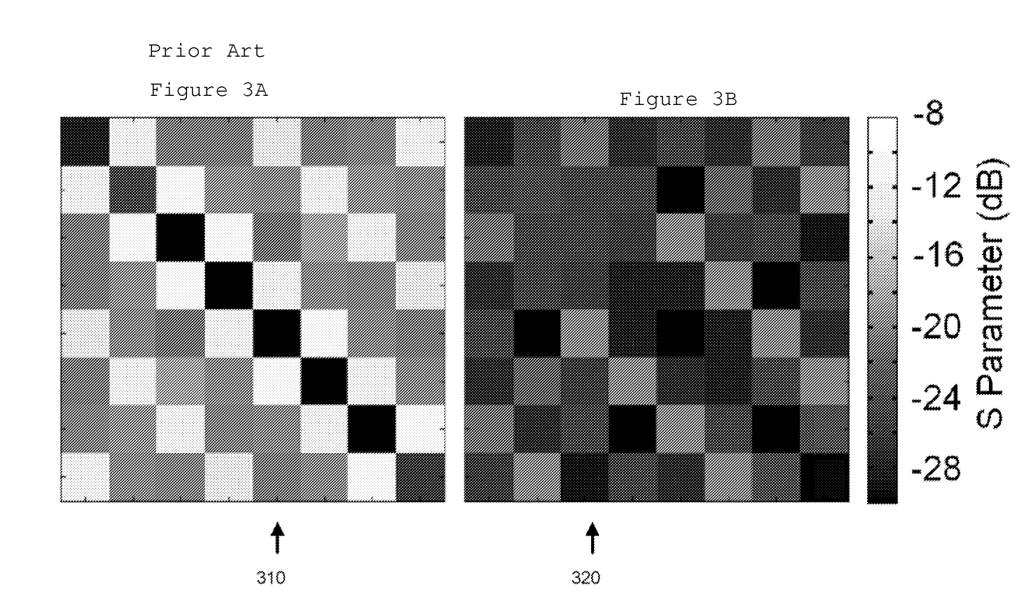

FIG. 3A shows an exemplary illustration of exemplary coupling matrices (e.g., S21) for the two 8-element exemplary embodiments (e.g., the coil 120), and the values shown along the diagonal can be S11 reflection values. When the coil elements of the exemplary CDA (e.g. the coils 120) can be made active, the distribution of coupling changed, with much less coupling between next nearest neighbors (e.g., approximately −20 dB) and higher coupling between neighbors (e.g., approximately −12 dB), which can be seen in an exemplary image 310 of FIG. 3A of the exemplary CDA (e.g., the coils 120). Also as shown in image 310 of FIG. 3B, high coupling between coils on opposite sides of the phantom can be seen. In contrast the exemplary triangular array (e.g., the coils 130) can be straightforward to decouple since once a coil can be decoupled from its neighbors and its next nearest neighbors it can be unaffected by any changes to the rest of the array. Coupling between elements can be −20 dB or less for all coil pairs, which can be seen in image 320. The exemplary birdcage, CDA and triangle array can use scanner transmitter reference voltages of 119, 106 and 100 volts respectively. The overall excitation pattern (not shown) can be similar for each coil, apart from drop-outs due to coupling in the birdcage and a bias towards the driving end of the CDA.

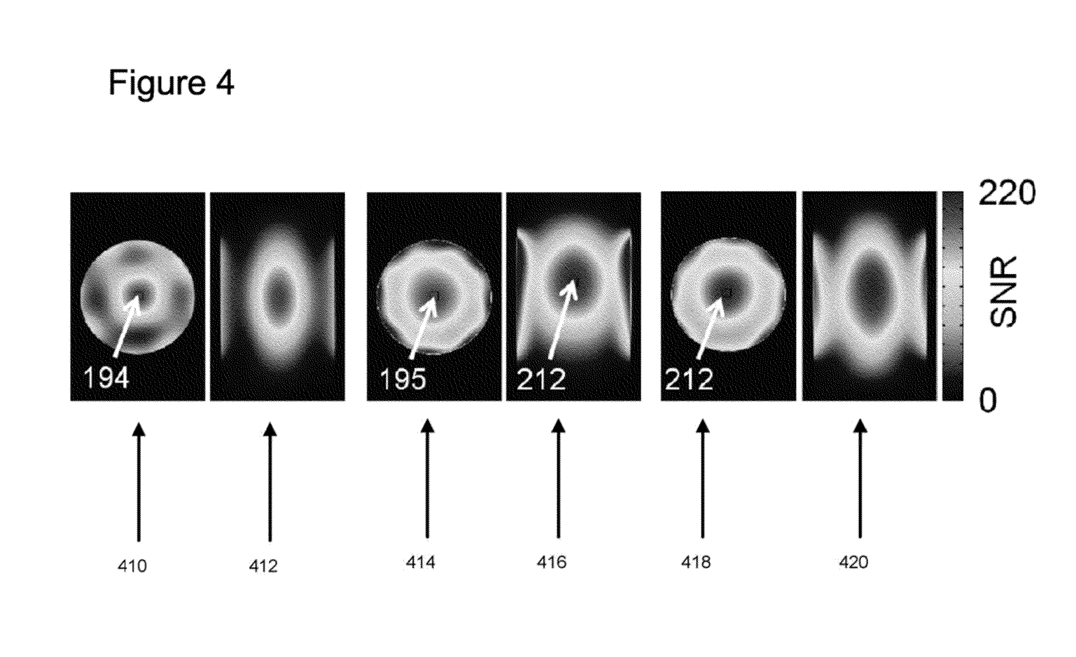

SNR plots are shown in FIG. 4. Exemplary plots 410 and 412 show SNR plots for the exemplary high pass birdcage (e.g., the coils 110), exemplary plots 414 and 416 show SNR plots for the exemplary CDA (e.g., the coils 120), and exemplary plots 418 and 420 show SNR plots for the exemplary triangular array (e.g., the coils 130). Both exemplary 8 channel arrays illustrate a comparable SNR, with the CDA having higher SNR in the periphery.

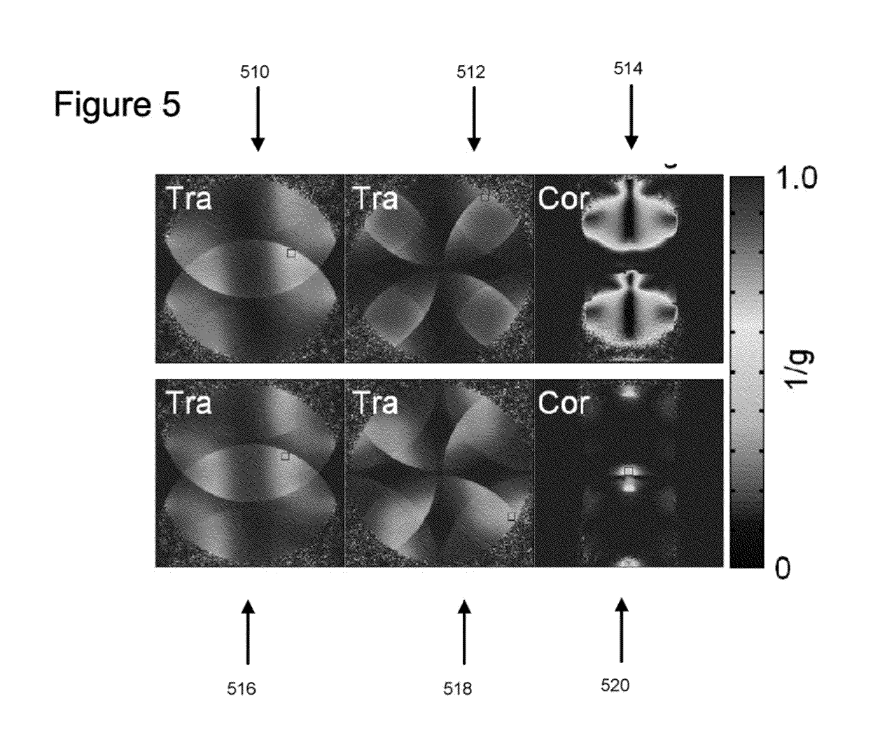

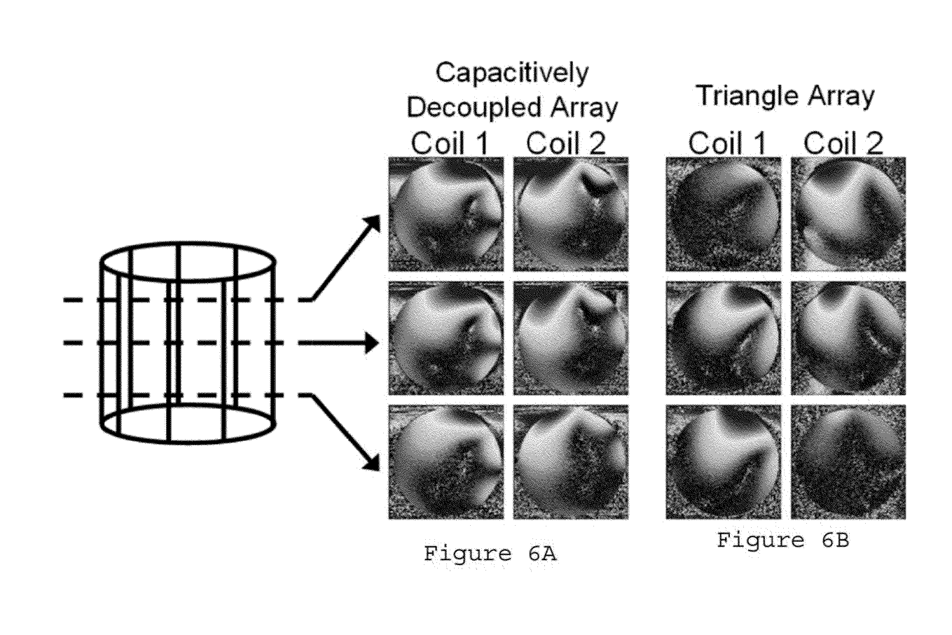

The exemplary triangular coil shows performance advantages in the exemplary g-factor maps, for example, as shown in the illustration of FIG. 5. Exemplary g-factor maps 510, 512, 514 can be provided as examples for the exemplary CDA coil (e.g., the coil 120), while g-factor maps 516, 518, and 520 can be for the exemplary Triangular Array (e.g., the coil 130). G-factor maps 510 and 516 can illustrate “X3,” g-factor maps 512 and 518 illustrate “2X2,” and g-factor maps 514 and 520 can illustrate “X2” along Z. G-factor values in an axial plane can be similar for the two coils, although attempting to accelerate along Z with a coronal slice can cause substantial noise amplification with the CDA since the exemplary CDA elements can have no variation in that direction. The exemplary alternating triangular elements can provide encoding along Z for both reception and transmission. Illustration of exemplary B1+ maps for individual elements are shown in FIGS. 6A and 6B, which illustrate that that Coil 1 and Coil 2 can, for example, swap intensity as you move along Z for the triangle coil but not for the CDA.

As provided in the exemplary results of certain exemplary embodiments, the exemplary triangle array design operates appropriately, without obvious penalty associated with the exemplary design.

Exemplary Embodiments of the Triangle Array Design

Exemplary triangle array designs can facilitate explicit decoupling of 1st and 2nd order neighbors, which can provide a highly decoupled array. With less power coupled to other ports, it can be more efficient, and the B1 variation along Z can facilitate acceleration along Z for parallel transmit and/or receive. In certain exemplary embodiments of the present disclosure, the exemplary inductive coupling between array elements can be significantly low. Efficiency for transmit and/or receive modes can be high because the elements can be configured as large loops, for example, with no shielding or gaps between them. The exemplary coil can be easy to tune and match because each element can behave independently from the other elements.

In certain exemplary embodiments of the present disclosure, when used as a receive coil, it can be possible to apply the acceleration through SENSE (e.g., Sensitivity Encoding) or GRAPPA (e.g., Generalized Auto-calibrating Partially Parallel Acquisitions) with the acceleration in the Z direction because elements with alternating orientations (e.g., big end of the triangle to one end or the other) can have differing sensitivity profiles along the Z direction. Thus, it can be possible to accelerate along any axis.

In certain exemplary embodiments of the present disclosure, when used as a transmit array, the low coupling between the elements can improve the efficiency of the coil because power may not be coupled back up the cables of other elements. Additionally, when used as a transmit array in a parallel transmit arrangement, the diverse B1+ profiles, with variation in Z direction, as well as X and Y directions, can facilitate a greater control over the B1+ field produced within the volume of the coil, for example, through techniques such as RF shimming and/or accelerated spatially tailored excitations.

According to certain exemplary embodiments of the present disclosure, it is possible to characterize, utilize and/or include several design elements. For example, according to certain exemplary embodiments, an array can be provided which can include multiple triangular loops (e.g., eight loops). By providing the exemplary loops in a triangular shape, it can be possible to decouple neighboring elements, for example, through control of the shared capacitors in their shared edge (e.g., the same or similar to a traditional decoupling technique), but it can also be possible to decouple the next nearest neighbors, for example, through inductive decoupling, since their corners can be in close proximity. This can be important because in normal arrays, there can be a limit to only decoupling the neighboring coils, and the next nearest neighbor coils can still have substantial coupling. For exemplary receive coils, exemplary embodiments of the present disclosure can address this issue by implementing preamp decoupling, which can minimize the current that can flow in the coils.

When using certain previously known array designs to transmit, as can be the case at high field with parallel transmission techniques, preamp decoupling may not be available to limit the current on the coils, and the coupling to next nearest neighbors can be problematic. Thus, an exemplary design of an array arrangement can, decouple every coil from its neighbor and its next nearest neighbors, and provide a highly decoupled array that can be very suitable for transmit-receive applications. In addition, the exemplary triangular shape of the elements, with alternating orientations, can provide coil profiles with variation along Z (e.g., the axis of the cylinder) which can be beneficial for many applications.

The levels of decoupling can be a beneficial element of the exemplary design. Neighboring coils can share an edge, and can be decoupled using shared capacitors, and the corners of the next nearest neighbor coils in exemplary designs can come close enough to decouple them using an inductive decoupling circuit. Thus, for example, each coil can be decoupled from both its neighbors and its next nearest neighbors. Thus, the exemplary coil array can include an efficient and highly decoupled transmit array, while retaining performance characteristics as a receive array.

Exemplary Triangular Antenna System

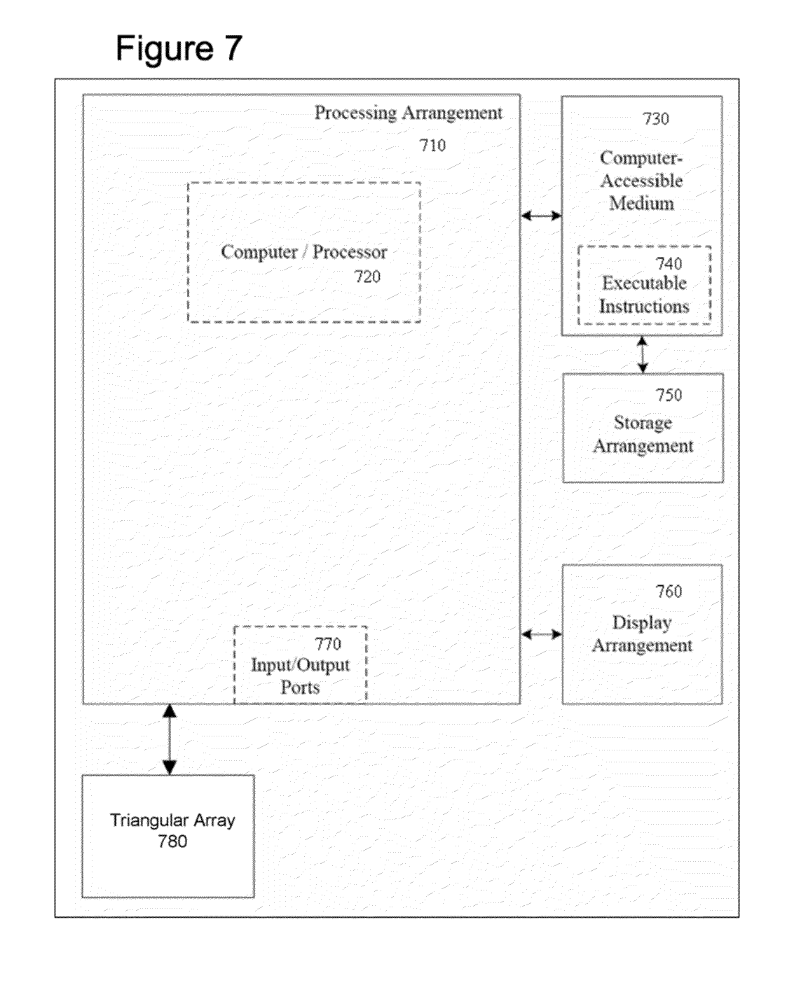

FIG. 7 shows a block diagram of an exemplary embodiment of a system according to the present disclosure. For example, exemplary procedures in accordance with the present disclosure described herein can be performed by a processing arrangement and/or a computing arrangement 710 and a triangular array arrangement 780. Such processing/computing arrangement 710 can be, for example, entirely or a part of, or include, but not limited to, a computer/processor 720 that can include, for example, one or more microprocessors, and use instructions stored on a computer-accessible medium (e.g., RAM, ROM, hard drive, or other storage device).

As shown in FIG. 7, for example, a computer-accessible medium 730 (e.g., as described herein above, a storage device such as a hard disk, floppy disk, memory stick, CD-ROM, RAM, ROM, etc., or a collection thereof) can be provided (e.g., in communication with the processing arrangement 710). The computer-accessible medium 730 can contain executable instructions 740 thereon. In addition or alternatively, a storage arrangement 750 can be provided separately from the computer-accessible medium 730, which can provide the instructions to the processing arrangement 710 so as to configure the processing arrangement to execute certain exemplary procedures, processes and methods, as described herein above, for example.

Further, the exemplary processing arrangement 710 can be provided with or include an input/output arrangement 770, which can include, for example, a wired network, a wireless network, the internet, an intranet, a data collection probe, a sensor, etc. As shown in FIG. 7, the exemplary processing arrangement 710 can be in communication with an exemplary display arrangement 760, which, according to certain exemplary embodiments of the present disclosure, can be a touch-screen configured for inputting information to the processing arrangement in addition to outputting information from the processing arrangement, for example. Further, the exemplary display 760 and/or a storage arrangement 750 can be used to display and/or store data in a user-accessible format and/or user-readable format.

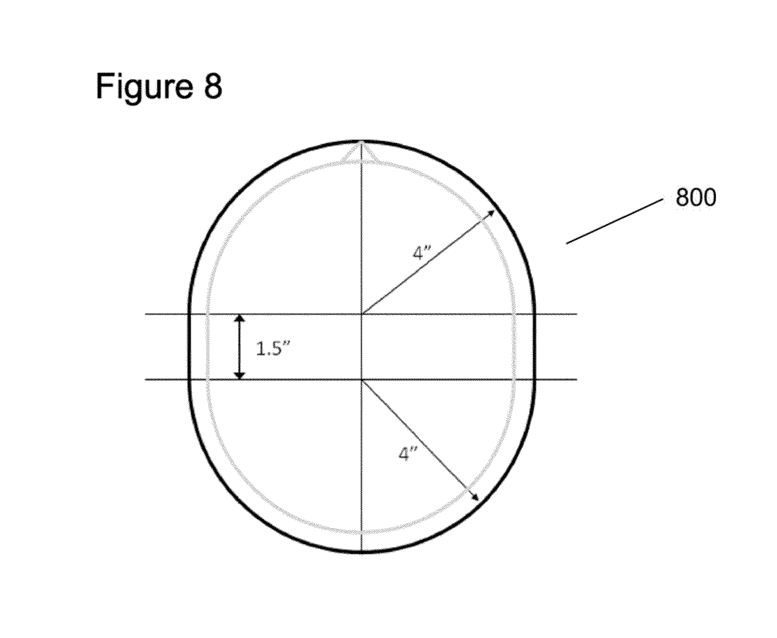

FIG. 8 is an illustration of exemplary dimensions for a cross-section for an exemplary triangular head array 800 according to certain exemplary embodiments of the present disclosure. As illustrated, an exemplary triangular head array can have a four inch diameter with a one and a half inch elongation, which can generally fit around the average human head. Other dimensions can also be possible, which can have similar or different dimensions than those illustrated in FIG. 8.

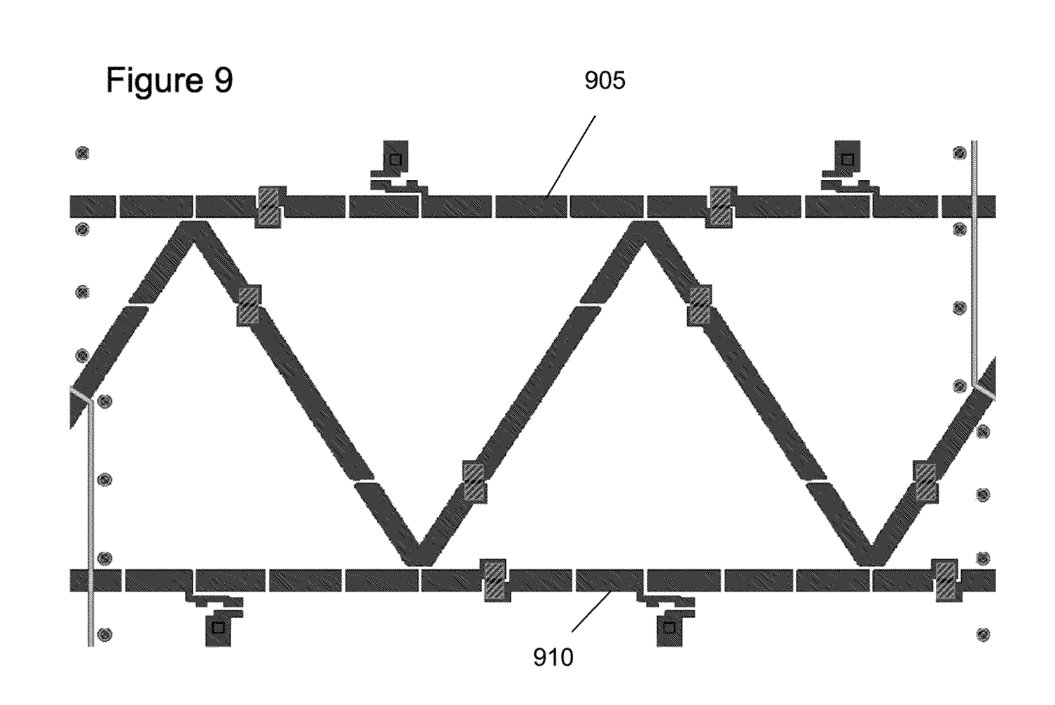

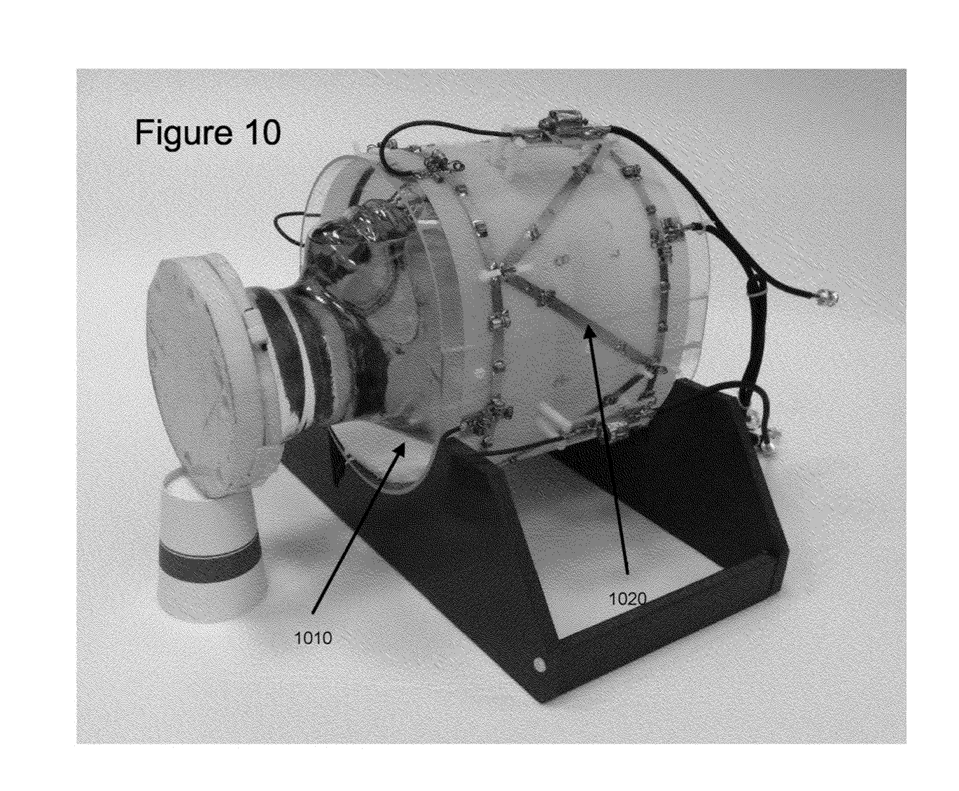

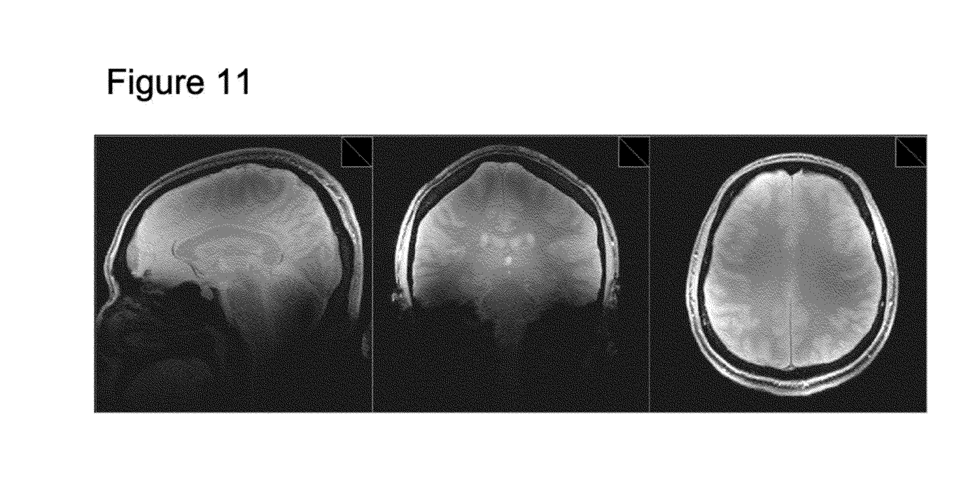

FIG. 9 is an illustration of an exemplary circuit board design for an exemplary triangular array (e.g., a 7T triangular head array). Two boards 905, 910 can be used to construct an exemplary 8-element array. FIG. 10 shows an illustration of another exemplary triangular array implementation. The array 1020 illustrated in FIG. 10 on glass jar 1010 can be an exemplary implementation of the circuit design illustrated in FIG. 9. FIG. 11 shows a set of exemplary illustrations of exemplary head images acquired with the exemplary triangular array shown in FIG. 10.

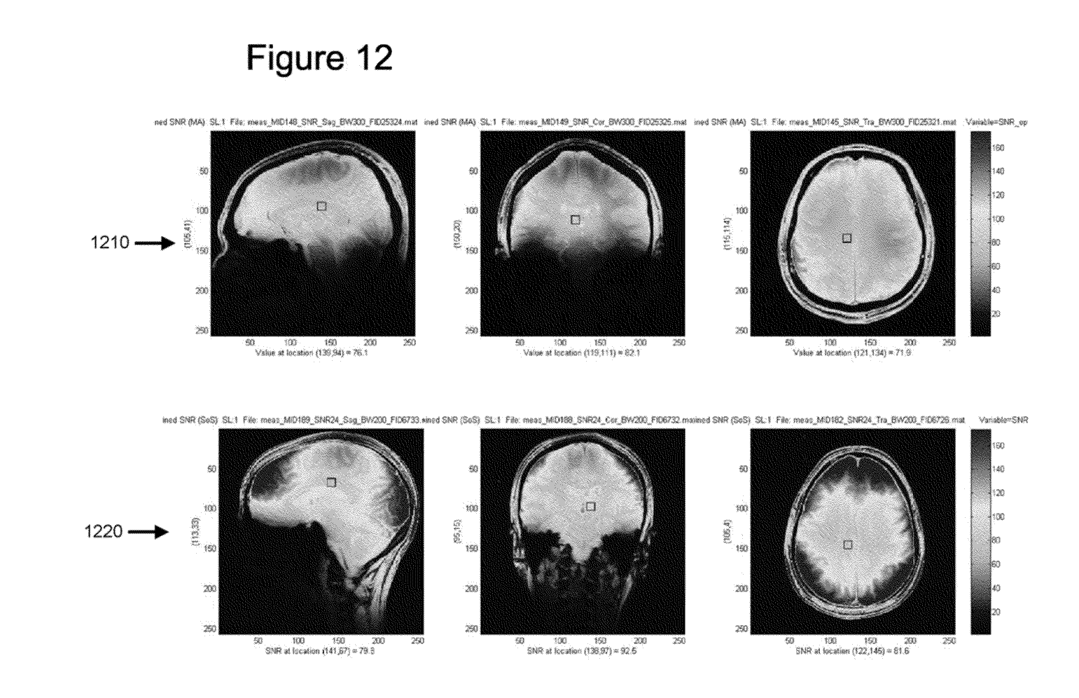

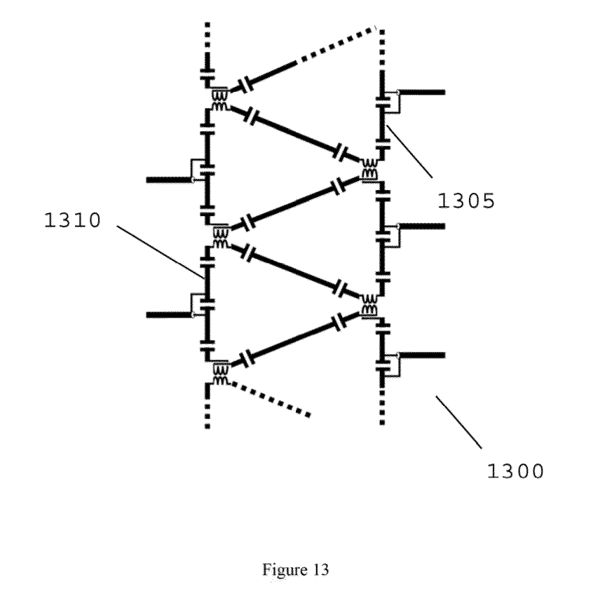

FIG. 12 shows a set of exemplary illustrations of exemplary SNR ratio. Specifically, top row 1210 can illustrate SNR maps from different views for an exemplary triangular head array and a reference voltage of 200 volts, for example, as recorded by the exemplary embodiment shown in FIG. 10. For comparison purposes, a bottom row 1220 can illustrate SNR maps from different views for a Nova Medical® 24-channel head array having a reference voltage of 232 volts.

Exemplary Shielding

B₁⁺ fields of exemplary coil implementation can drop off too quickly along the z direction, and inductance can limit the design from being lengthened. Therefore, a shielded version of the exemplary triangular array can be used that can have greater length in z for head imaging at 7T, without reaching the inductance limit of large elements, and can improve the SNR, for example, in the cerebellum and the brain stem. End caps can aid in boosting SNR in the head apex as well as the center. The exemplary shielded triangular array can be used in parallel transmit application while also having a high receive sensitivity, facilitating a high image resolution (e.g., 0.25×0.25×1.5 mm). Utilizing the exemplary shielded triangular array with parallel excitation can generate a more homogeneous image, and a more consistent contrast can be acquired where a traditional circularly polarized (“CP”) mode excitation can fail. The exemplary shielded triangular array can facilitate decoupling of the next nearest neighbors, and can create B₁⁺ profiles having variations along the z direction.

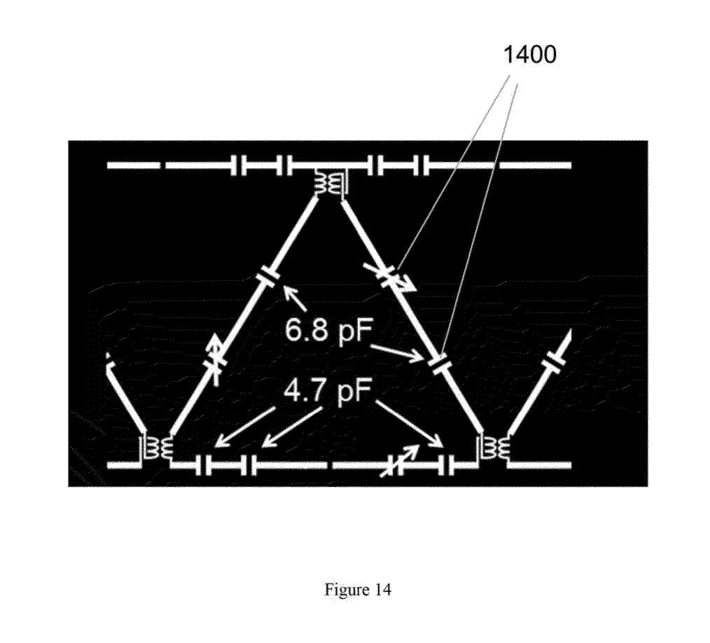

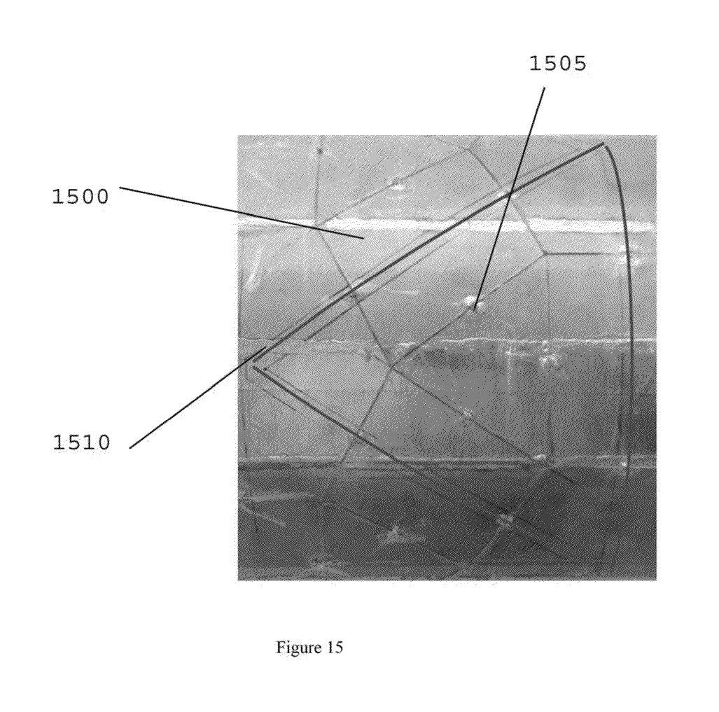

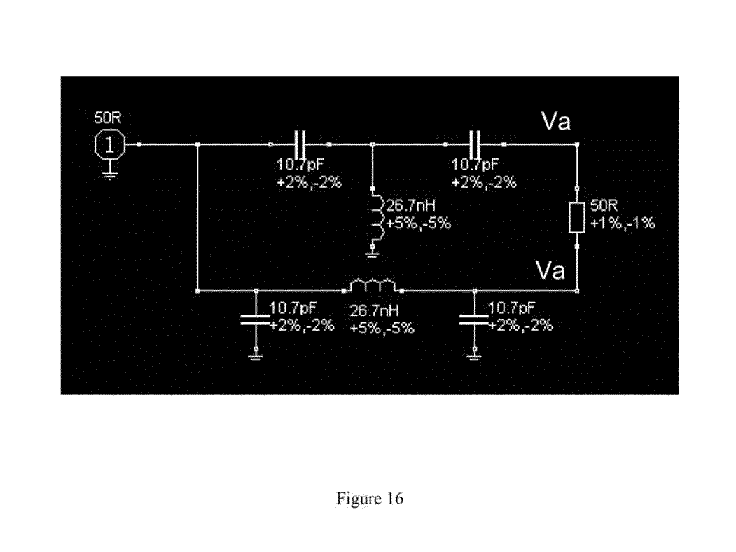

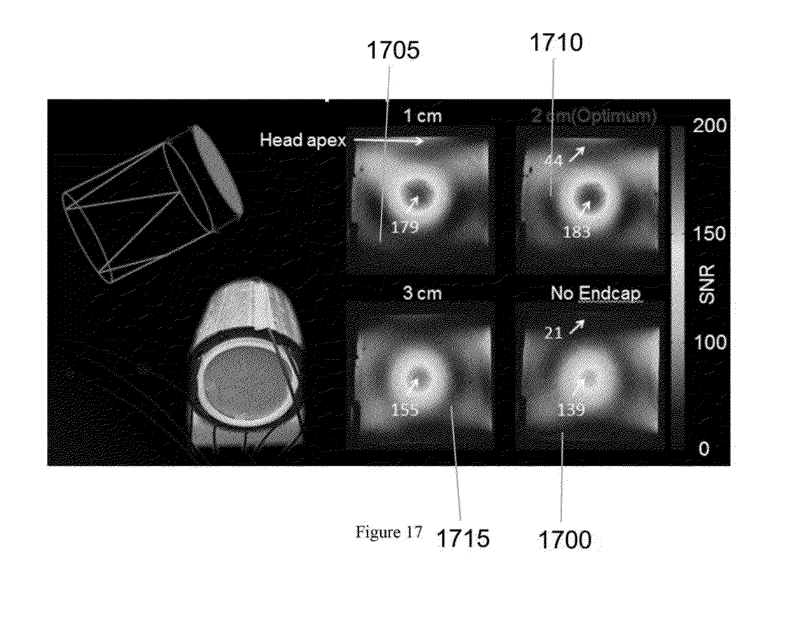

An exemplary shielded triangular array 1300 is shown in FIG. 13, where the exemplary shielded triangular array, having two boards 1305 and 1310, can be about 2 cm longer than the exemplary non-shielded triangular array. FIG. 14 shows an exemplary diagram illustrating exemplary components of an exemplary shielded triangular head array. For example, capacitors in shared legs (e.g., capacitors 1400) can provide greater than −20 dB coupling between neighbors. As shown in FIG. 15, the exemplary shield can be partitioned or segmented into patches 1500 to prevent gradient coil induced eddy currents in the shield, which can occur in the kilohertz frequency range. The shield can also be, or appear to be, continuous at various RF frequencies (e.g., 300 MHz) to facilitate shielding of the triangular array. Sections can be connected by 330 pF capacitors 1505 to provide RF continuity. Capacitors can be placed so that RF continuity can be provided such that an RF current path 1510 can exist which can track the path of the underlying triangular coil element. FIG. 16 shows an exemplary circuit diagram for a matching circuit for the exemplary shielded triangular array. A 180 degree Balun can provide a 180 degree phase shift between Va and Vb to prevent cable currents. FIG. 17 shows exemplary images of endcap optimization with no endcap 1700, an endcap placed at 1 cm 1705, an endcap placed at 2 cm 1710 and an endcap placed at 3 cm 1715, for the exemplary shielded triangular array. It can be seen that the optimal endcap distance can be 2 cm, which can illustrate an improvement in the SNR at the apex SNR and in the central SNR.

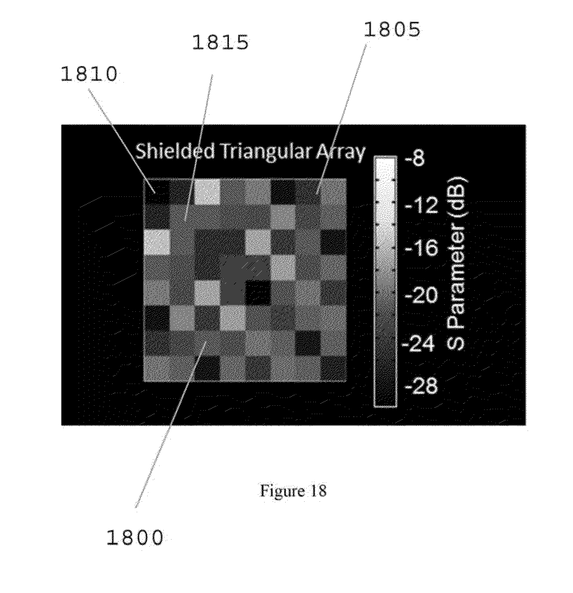

FIG. 18 illustrates an exemplary image of a coupling matrix for the exemplary shielded triangular array. S₂₁ coupling between elements 3 and 7, for example, can be plotted at positions (3, 7) (element 1800) and (7, 3) (element 1805) in the matrix. For example, coupling can be −16 dB or greater. S₁₁ reflection of each element is represented on the diagonal of the matrix (1, 1) (element 1810), (2, 2) (element 1815) etc. The coil element Q ratio can be 6, while the coil ratio Q for the non-shielded triangular array can be 6.4.

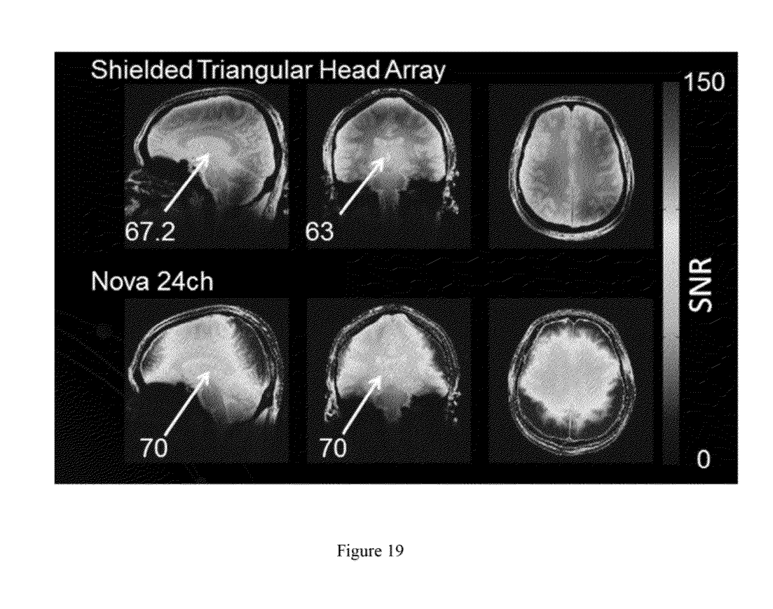

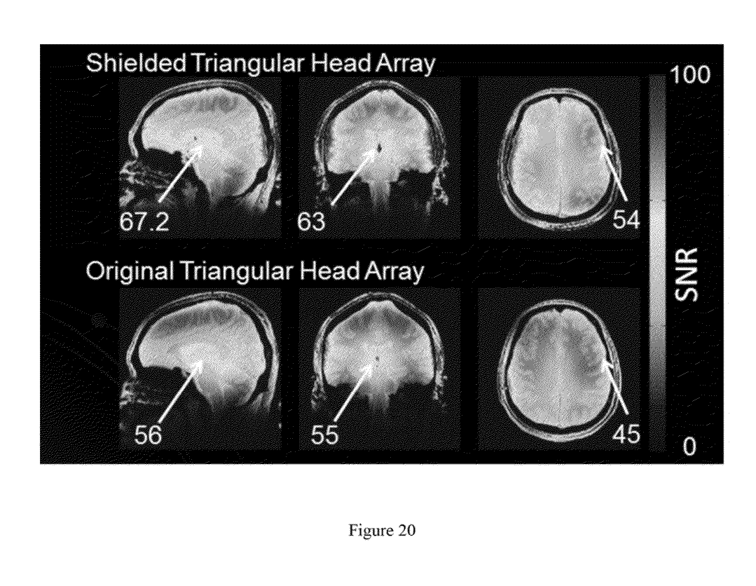

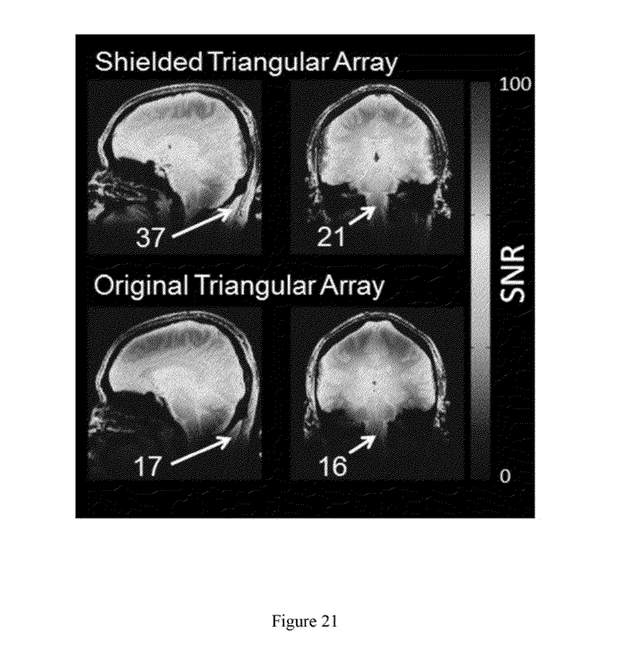

FIG. 19 shows a set of exemplary images illustrating a comparison of the exemplary shielded triangular array compared to a Nova 24ch system. For example, the exemplary shielded triangular array can be driven in a circular polarization mode with an 8ch parallel transmit system. The center SNR can be about 95% of the center SNR of a Nova 24ch system. FIGS. 20 and 21 illustrate exemplary images of an SNR comparison between the exemplary shielded triangular array and the exemplary non-shielded triangular array. For example, the exemplary shielded triangular array can have improved SNR as compared to the exemplary non-shielded triangular array.

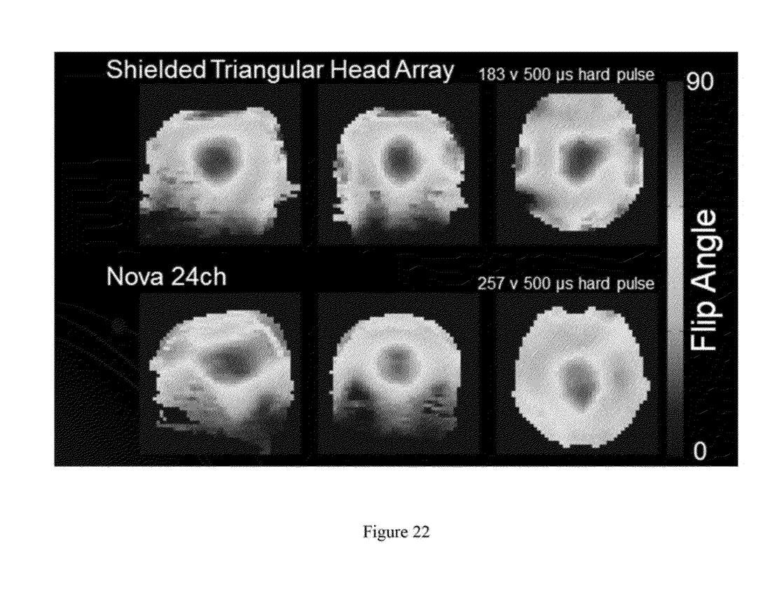

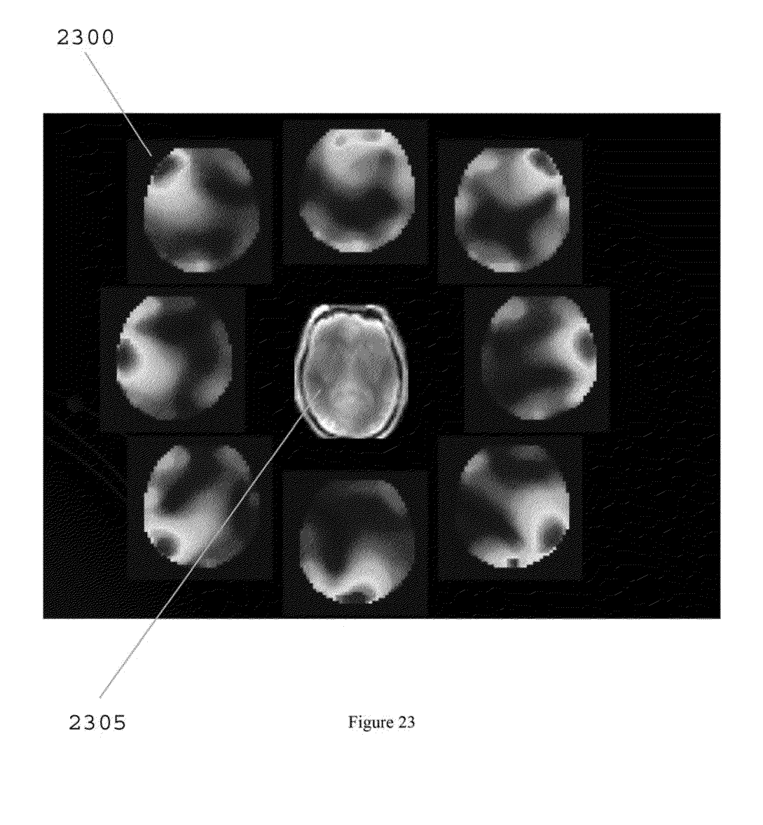

FIG. 22 shows a set exemplary images illustrating B₁⁺ comparison between the exemplary shielded triangular array and a Nova 24ch array. The exemplary shielded triangular array can drive the 8 elements with a birdcage-like phase distribution which can produce a similar B₁⁺ pattern to the Nova transmit birdcage. Additionally, the transmit efficiency for the exemplary shielded triangular array can be higher as compared to the Nova transmit birdcage.

FIG. 23 shows a set of exemplary images illustrating individual B₁⁺ maps for the exemplary shielded triangular array. The B₁⁺ maps for an individual coils 2300 illustrate distinct profiles. An exemplary image obtained in the same axial slice while transmitting with all elements 2305 is also shown.

The foregoing merely illustrates the principles of the disclosure. Various modifications and alterations to the described embodiments will be apparent to those skilled in the art in view of the teachings herein, and especially in the appended numbered paragraphs. It will thus be appreciated that those skilled in the art will be able to devise numerous systems, arrangements, and methods which, although not explicitly shown or described herein, embody the principles of the disclosure and are thus within the spirit and scope of the disclosure. In addition, all publications and references referred to above are incorporated herein by reference in their entireties. It should be understood that the exemplary procedures described herein can be stored on any computer accessible medium, including a hard drive, RAM, ROM, removable disks, CD-ROM, memory sticks, etc., and executed by a processing arrangement which can be a microprocessor, mini, macro, mainframe, etc. In addition, to the extent that the prior art knowledge has not been explicitly incorporated by reference herein above, it is explicitly being incorporated herein in its entirety. All publications referenced above are incorporated herein by reference in their entireties.

### EXEMPLARY REFERENCES

The following references are hereby incorporated by reference in their entirety.
[1] Breton E. NMR Biomed. 2010 May; 23(4):368-74.
[2] Klose U, Med. Phys. 19 (4), 1992.
[3] Kellman P. MRM 54:1439-1447 (2005).

What is claimed is:

1. An array arrangement, comprising:
a plurality of triangular antenna arrangements configured to at least one of transmit or receive at least one magnetic resonance signal.

2. The arrangement of claim 1, further comprising:
a processing arrangement configured to generate information associated with a magnetic resonance image based on the at least one magnetic resonance signal.

3. The arrangement of claim 1, wherein at least two ones of the triangular antenna arrangements have alternating orientations.

4. The arrangement of claim 1, wherein at least two neighboring ones of the triangular antenna arrangements are decoupled using at least one capacitor in at least one leg shared by the at least two neighboring ones of the triangular antenna arrangements.

5. The arrangement of claim 1, wherein at least two neighboring ones of the triangular antenna arrangements are decoupled by overlapping the at least two neighboring one of the triangular antenna arrangements.

6. The arrangement of claim 1, wherein next nearest neighboring ones of the triangular antenna arrangements are decoupled using an inductive circuit.

7. The arrangement of claim 4, wherein next nearest neighboring ones of the triangular antenna arrangements are decoupled using an inductive circuit.

8. The arrangement of claim 1, wherein next nearest neighboring ones of the triangular antenna arrangements are decoupled using a capacitive circuit.

9. The arrangement of claim 4, wherein next nearest neighboring ones of the triangular antenna arrangements are decoupled using a capacitive circuit.

10. The arrangement of claim 1, wherein the triangular antenna arrangements comprises at least 8 triangular antenna arrangements.

11. The arrangement of claim 1, wherein the triangular antenna arrangements are structured as large loops.

12. The arrangement of claim 1, wherein the triangular antenna arrangements are unshielded.

13. The arrangement of claim 1, wherein gaps between each of the triangular antenna arrangements are provided that are sized close to or equal to zero.

14. The arrangement of claim 3, wherein the triangular antenna arrangements have different sensitivity profiles.

15. The arrangement of claim 1, wherein the triangular antenna arrangements have a substantially low coupling when the triangular antenna arrangements are configured to transmit the at least one magnetic resonance signal.

16. The arrangement of claim 15, wherein the coupling is less than −15 dB.

17. The arrangement of claim 1, wherein the triangular antenna arrangements are configured to be used in parallel imaging when the triangular antenna arrangements transmit the at least one magnetic resonance signal.

18. The arrangement of claim 1, further comprising a preamp decoupling arrangement configured to preamp decouple the triangular antenna arrangements when the triangular antenna arrangements receive the at least one magnetic resonance signal.

19. The arrangement of claim 1, further comprising a shield arrangement configured to shield the triangular antenna arrangements.

20. The arrangement of claim 19, wherein the shield arrangement is partitioned to reduce gradient coil induced eddy currents on the shield.

21. The arrangement of claim 20, wherein a pattern of the partition is configured to track a current path of the shielded triangular antennas arrangements.

22. The arrangement of claim 20, further comprising at least one capacitor coupled to at least one partition, the at least one capacitor configured to provide radio frequency continuity in a path which tracks a current path of the shielded triangular antennas arrangements.

23. The arrangement of claim 19, further comprising an end cap provided at an end of each of the triangular antenna arrangements.

24. The arrangement of claim 19, further comprising an end cap provided on at least one end of at least one of the antenna arrangements.
